(19) United States
(12) Patent Application Publication
(10) Pub. No.: US 2026/0275510 A1
(43) Pub. Date: Sep. 17, 2026

(54) LOW TEMPERATURE OPTICAL WAVEGUIDE DEVICE FABRICATION METHOD

(71) Applicant: ECOLE POLYTECHNIQUE FEDERALE DE LAUSANNE (EPFL), Lausanne (CH)

(72) Inventors: Zheru QIU, Crissier (CH); Zihan LI, St-Sulpice (CH); Tobias KIPPENBERG, St-Sulpice (CH)

(21) Appl. No.: 19/472,221

(22) PCT Filed: Apr. 2, 2024
(86) PCT No.: PCT/IB2024/053188

§ 371 Date: Oct. 3, 2025

(30) Foreign Application Priority Data
Apr. 6, 2023 (EP) 23167100.9

(51) Int. Cl. C23C 16/40; C23C 16/505; G02B 6/136; H01J 37/32

(52) U.S. Cl. CPC C23C 16/402; C23C 16/505; G02B 6/136; H01J 37/321

(57) ABSTRACT

The present invention concerns an optical waveguide device (1) fabrication method comprising providing at least one optical waveguide or optical waveguide core (3); and depositing at least one silicon dioxide layer or material (15) onto the at least one optical waveguide or optical waveguide core (3) to form a cladding or passivation layer of the optical waveguide device (1). The at least one silicon dioxide layer or material (15) is deposited by plasma-enhanced chemical vapor deposition using precursors comprising or consisting of silicon tetrachloride and at least one oxidizer, the plasma being an inductively coupled plasma.

### CROSS-REFERENCE TO RELATED APPLICATIONS

The present application claims priority to the European Application EP23167100.9 that was filed on Apr. 6, 2023, the entire contents thereof being herewith incorporated by reference.

### FIELD OF THE INVENTION

The present invention relates to an optical waveguide device preparation or fabrication method, or a photonic integrated circuit (PIC) preparation or fabrication method. The present invention more particularly concerns a low temperature passive optical waveguide preparation or fabrication method providing an optical waveguide device having a passivation or cladding layer of reduced optical loss, in particular, having reduced absorption from OH bonds.

### BACKGROUND

With the maturing of emerging low-loss integrated photonics platforms such as thin film LiNbO₃, LiTaO₃, BaTiO₃, GaP and AlGaAs on insulator, a low-temperature process for depositing low optical loss cladding material is now of critical importance for waveguide passivation.

The utilization of crystalline materials as waveguide cores allows efficient second-order nonlinearity and enables key device functionalities like agile electro-optic tuning and highly efficient nonlinear wavelength conversion. However, challenges arise as many of such advanced materials are not tolerant of elevated temperature. Technologies such as erbium doped silicon nitride amplifiers can also benefit from lower temperature exposure during fabrication.

A long-standing challenge for low-temperature low-loss SiO₂ cladding deposition is the strong absorption peak of OH bonds around 1380 nm with a long absorption tail extending to longer wavelengths. This notorious absorption peak originates from the hydrogen impurity introduced by the commonly used silicon precursors such as SiH₄, SiH₂Cl₂, and Si(OC₂H₅)₄ (TEOS) in chemical vapor deposition processes. This absorption peak can only be shifted or removed by using expensive deuterated precursors or long annealing at very high temperatures>1100° C., such as 1200° C., far beyond the thermal budgets of many platforms and much more than what platforms such as LNOI can tolerate.

The article by Warren Jin et al. entitled “Deuterated silicon dioxide for heterogeneous integration of ultra-low-loss waveguides”, published in Opt. Lett., 45, pages 3340-3343 (2020) discloses SiO₂ films deposited at low temperature by plasma-enhanced chemical vapor deposition (PECVD) from a deuterated silane (SiD₄) precursor. The isotopic substitution of deuterium for hydrogen in the SiO₂ film shifts the fundamental SiO—H absorption from its peak value at 2.73 μm to 3.74 μm. In the near infrared, the corresponding first overtone of this absorption shifts from 1390 nm to 1870 nm, reducing absorption loss in the technologically important C and O telecommunications bands. However, deuterium is inherently expensive, is of low natural abundance and requires an energy-intensive isotope separation process thus limiting widespread uptake in optical waveguide device fabrication. Moreover, remaining OH absorption due to the incomplete isotope separation and the isotope shifted OD absorption can also impact wide-band applications such as frequency comb generation and parametric amplification.

JP H0741951 discloses a high temperature glass core film deposition that assures that the glass core film does not peel off.

US2003/0152702 discloses the advantages of a mixed optical device in which the waveguide core is defined by a polymer material, and discloses a method for depositing a silicon dioxide on the polymer waveguide core using the precursors SiH₄ and oxygen O₂.

Agoal of the present invention is to provide a solution to the above-mentioned inconveniences, and in particular, to provide an optical waveguide device preparation or fabrication method that assures low temperature deposition and assures provision of a passivation or cladding layer of reduced optical loss, in particular, having reduced absorption from OH bonds.

### SUMMARY

It is therefore one aspect of the present disclosure to provide an optical waveguide device fabrication method that addresses the above-mentioned inconveniences and needs.

The optical waveguide device fabrication method may comprise providing at least one optical waveguide or optical waveguide core; and depositing at least one silicon dioxide layer or material onto the at least one optical waveguide or optical waveguide core to form a cladding or passivation layer of the optical waveguide device; wherein the at least one silicon dioxide layer or material is deposited by plasma-enhanced chemical vapor deposition (PECVD) using precursors comprising or consisting of silicon tetrachloride (SiCl₄) and at least one oxidizer, the plasma being an inductively coupled plasma (ICP).

The at least one oxidizer may include oxygen (O₂) and/or nitrous oxide (N₂O).

The at least one silicon dioxide layer or material may be deposited by inductively coupled plasma plasma-enhanced chemical vapor deposition (ICP-PECVD).

An inductively coupled plasma (ICP) excitation power, provided by a radio frequency (RF) power source or voltage generator during deposition of the at least one silicon dioxide layer or material, may be greater than 400 W. This, for example, may provide a cladding or passivation layer of the optical waveguide device of lower optical loss. The inductively coupled plasma (ICP) excitation power may be greater than or equal to 1600 W.

A bias radiofrequency power, provided by a radio frequency (RF) bias source or voltage generator during deposition of the at least one silicon dioxide layer or material, may be greater than 100 W. This, for example, may reduce hygroscopicity of the cladding or passivation layer of the optical waveguide device. The bias radiofrequency power may be greater than or equal to 180 W. The bias radiofrequency power may be between 180 W and 400 W.

The at least one silicon dioxide layer or material may be deposited on the optical waveguide or optical waveguide core at temperature less than or equal to 300° C.

The precursors may be hydrogen-free precursors, or hydrogen isotope-free precursors, or deuterium-free precursors.

The provided at least one optical waveguide or optical waveguide core may be included on a photonic integrated circuit (PIC), or included on at least one substrate, or included on at least one CMOS substrate.

The at least one optical waveguide or optical waveguide core may comprise silicon nitride, erbium-doped silicon nitride, or lithium niobate.

The method can further include carrying out thermal annealing only after deposition of the at least one silicon dioxide layer or material. The thermal annealing can be carried out at a temperature of 500° C., or between 400° C. and 500° C., and/or for a time duration of between 30 and 90 minutes.

The deposited at least one silicon dioxide layer or material is, for example, OH absorption-free or OH absorption peak-free, or SiOH absorption-free or SiOH absorption peak-free.

The present disclosure also concerns an optical waveguide device produced or provided by the above method, and a photonic integrated circuit including the optical waveguide device produced or provided by the above method.

Other further advantageous features can be found in the dependent claims.

The above and other objects, features and advantages of the present invention and the manner of realizing them will become more apparent, and the invention itself will best be understood from a study of the following description with reference to the attached drawings showing some preferred embodiments of the invention.

### BRIEF DESCRIPTION OF THE DRAWINGS

The accompanying drawings, which are incorporated herein and constitute part of this specification, illustrate the presently preferred embodiments of the invention, and together with the general description given above and the detailed description given below, serve to explain features of the invention.

FIGS. 1A to 1E schematically show a non-limiting and exemplary optical waveguide device fabrication method of the present disclosure, the indicated details are exemplary details, such as the indicated exemplary materials used.

FIG. 2A shows a cross sectional characterization measurement, measured from an optical waveguide ring resonator fabricated using the SiCl₄-based SiO₂ cladding deposition method according to the present disclosure, showing the fundamental TE mode of a Si₃N₄ ring resonator used as an optical loss probe.

FIG. 2B shows a top view scanning electron microscopy image of the SiO₂ cladding deposited on LNOI waveguides according to the deposition method of the present disclosure.

FIGS. 3A and 3B show measured waveguide loss as a function of wavelength of optical waveguide resonators fabricated by SiO₂ cladding deposited by low-pressure chemical vapor deposition (LPCVD) and annealed at 1200° C., via SiO₂ deposited using SiH₄ and by PECVD (300° C.), via SiCl₄ based PECVD (300° C.) according to the present disclosure, and annealed SiCl₄ based PECVD (500° C.) according to the present disclosure.

FIG. 4 schematically shows an inductively coupled plasma plasma-enhanced chemical vapor deposition (ICP-PECVD) tool or reactor.

FIG. 5A is a cross-sectional SEM image of a LiNbO₃ on insulator waveguides (LNOI) produced by the optical waveguide device fabrication method of the present disclosure. FIG. 5B shows the measured waveguide optical loss for the LiNbO₃ on insulator waveguides (LNOI) produced by the optical waveguide device fabrication method of the present disclosure. The relatively low loss manifests the compatibility of the method of the present disclosure with the technologically important LNOI photonics platform.

Herein, identical reference numerals are used, where possible, to designate identical elements that are common to the Figures. Also, the images are simplified for illustration purposes and may not be depicted to scale.

### DETAILED DESCRIPTION OF SEVERAL EMBODIMENTS

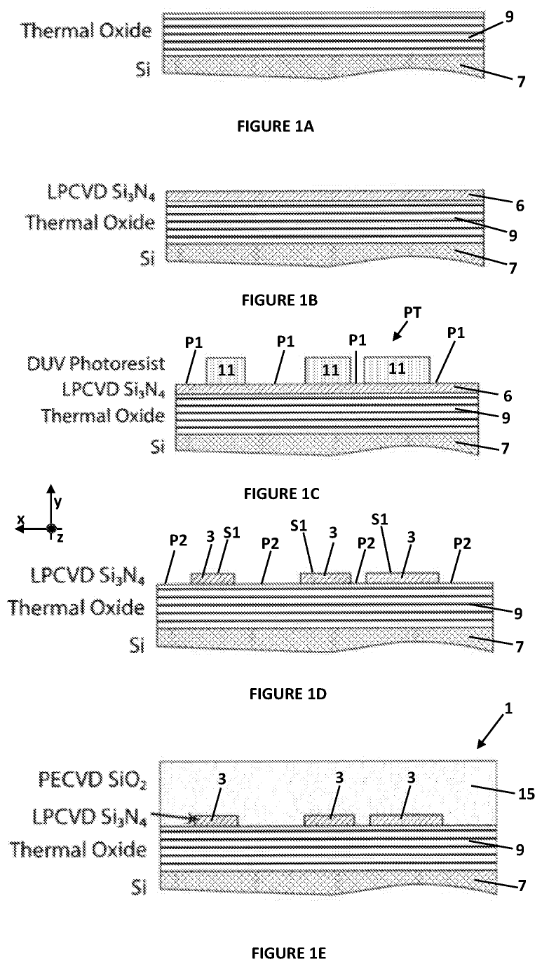

FIGS. 1A to 1F schematically show exemplary steps of an exemplary optical waveguide device fabrication method of the present disclosure.

The fabrication method is an optical waveguide device 1 or optical passive waveguide device 1 fabrication method.

The method includes providing at least one or a plurality of optical waveguides 3 or optical waveguide cores 3. This is shown in the exemplary embodiment schematically illustrated in FIG. 1D. FIGS. 1A to 1C show exemplary fabrication steps permitting to provide the plurality of optical waveguides 3 or optical waveguide cores 3 upon which a silicon oxide passivation or cladding layer or material 15 is subsequently deposited. These fabrication steps and the details shown and exposed below are to be understood as being exemplary, and non-limiting.

The optical waveguide 3 or optical waveguide core 3 may, for example, be an elongated waveguide or waveguide core (elongated, for example, in the z-direction, FIG. 1D showing a cross section in which the waveguide core 3 defines a plane defined by the x and y directions), extending linearly, or in a curved manner, and may for example extend in a curved manner to define a ring.

The optical waveguide 3 or optical waveguide core 3 may, for example, be or define an optical resonator, prior to and/or after deposition of a silicon oxide passivation or cladding layer or material 15.

The optical waveguide 3 or optical waveguide core 3 can be, for example, included on a photonic integrated circuit (PIC), or included on at least one (supporting) substrate or (supporting) layer 7, for example, a CMOS substrate.

The optical waveguide 3 or optical waveguide core 3 may, for example, comprise or consist of silicon nitride (for example, Si₃N₄), erbium-doped silicon nitride, lithium niobate LiNbO₃, lithium tantalate LiTaO₃, barium titanate BaTiO₃, gallium phosphide GaP, aluminum oxide Al₂O₃ or aluminium gallium arsenide AlGaAs.

The optical waveguide 3 or optical waveguide core 3 may be non-polymer, or may be a non-polymer optical waveguide 3, or a non-polymer optical waveguide core 3. The optical waveguide 3 or optical waveguide core 3 does not, for example, comprise or consist of a polymer or polymer material.

The optical waveguide 3 or optical waveguide core 3 in the illustrated exemplary embodiment of FIGS. 1A to 1E comprises Si₃N₄.

The optical waveguides 3 or optical waveguide cores 3 are provided on or included on the substrate 7. The substrate 7 may, for example, comprise or consist of silicon, sapphire, silicon carbide, lithium niobate, fused silica, or quartz.

The optical waveguides 3 or optical waveguide cores 3 are provided, in the illustrated exemplary embodiment of FIGS. 1A to 1C, by depositing a silicon nitride material or layer 6 on a silicon oxide layer 9 formed or deposited on the substrate 7. The silicon oxide layer 9 may, for example, have a thickness between 2 μm and 10 μm. The silicon oxide layer 9 forms, for example, a lower cladding layer or material of the optical wave device 1.

The substrate 7 is, for example, a silicon substrate, and the silicon oxide layer 9 is, for example, a thermal oxide layer produced by oxidation of silicon atoms on an upper portion of the Si substrate 9 which are converted to silicon oxide, as classically known to the skilled person (see, for example, Jaeger, Richard C. (2001), “Thermal Oxidation of Silicon”. Introduction to Microelectronic Fabrication, Upper Saddle River: Prentice Hall, ISBN 978-0-201-44494-0, the entire contents of which are incorporated herein by reference).

Silicon nitride 6 is deposited, for example, by low-pressure chemical vapor deposition (LPCVD) as known to the skilled person and may, for example, have a thickness between 0.1 μm and 0.9 μm. In the exemplary embodiment, a Si₃N₄ thin film is deposited via LPCVD from dichlorosilane and ammonia gas precursors at 770° C. in a single deposition run up to the desired thickness (see also, for example, previous reference by Jaeger, Richard C).

The optical waveguides 3 or optical waveguide cores 3 are, for example, formed using photolithography, for example, an ultraviolet or deep ultraviolet (DUV) photolithography process, or e-beam lithography.

The photolithography process may be carried out, for example, using stepper photolithography or step-and-repeat camera photolithography (for example, via an ASML PAS 5500/350C stepper, JSR M108Y resist, and Brewer DUV-42P coating). The process may include the following steps. A photoresist layer 11 (for example, JSR M108Y resist) may be coated or deposited (for example, directly) onto the silicon nitride material or layer 6 (see, for example, FIG. 1F). Photolithography or UV lithography is used to transfer a (geometric) pattern or structure from a photomask or optical mask PM to the photosensitive photoresist 11. Deep ultraviolet (DUV) photolithography using, for example, light LT of wavelength<400 nm, for example, in the range 193 nm-254 nm illuminates the photomask PM to define an exposure pattern on and in the photoresist 11 such that the resulting photoresist or photoresist polymer pattern PT can be transferred into the underlying layers or materials by etching.

The exposure UV or DUV light LT is passed through, for example, a chrome-on-quartz photomask PM, whose opaque areas act as a stencil of the desired pattern. The photoresist layer 11 may be baked before and/or after light exposure. The exposed photoresist areas then undergo a chemical development (for example, using a TMAH photoresist developer, which for example, is commercially available from the company JSR) to remove unwanted photoresist areas (photoresist remains in areas where the photomask blocked light exposure) and producing areas P1 that are open or exposing the silicon nitride material or layer 6 or a surface(s) thereof, that can be subsequently processed.

The above-described approach is a positive photoresist exposure approach. Alternatively, a negative photoresist exposure approach may also be used using negative photoresist.

The result of the photolithography process is the patterned or structured photoresist layer PT. The pattern or structure of the photoresist layer PT is transferred into the silicon nitride material or layer 6.

Etching is carried out to etch the exposed portion or portions P1 of the silicon nitride material or layer 6 to remove the exposed silicon nitride material to expose one or a plurality of portions P2 of the silicon oxide layer or material 7 located underneath. Etching is carried out, for example, preferably via dry etching such as plasma-etching as known to the skilled person in the art, for example, using an ICP-based high density plasma source.

In an exemplary embodiment, dry etching, or plasma etching of the silicon nitride material or layer 6 is carried out to form the one or more silicon nitride elongated waveguide cores may comprise, for example, carrying out anisotropic dry etching carried out using, for example, CₓF_{y}-based chemical substances. Oxygen, may, for example, be added in order to remove CF polymers created as an etching by-product. Etching can, for example, be carried out with CHF₃ and SF₆, and with O₂ also, serving to remove the etching by-product from chemical reactions between Si₃N₄ and CHF₃/SF₆.

Alternatively, a wet etch may be carried out using wet etches classically known to the skilled person in the art.

As a result, the plurality of optical waveguides 3 or optical waveguide cores 3 are provided (see, for example, FIG. 1D) and undergo further fabrication steps.

In accordance with the present disclosure, at least one silicon dioxide (SiO₂) layer or material 15 is deposited onto the optical waveguides 3 or optical waveguide cores 3 to form a cladding or passivation layer 15 of the optical waveguide device 1. At least one silicon dioxide (SiO₂) layer or material 15 is deposited by plasma-enhanced chemical vapor deposition PECVD using precursors comprising silicon tetrachloride SiCl₄ and at least one oxidizer. The at least one oxidizer includes, for example, oxygen O₂ and/or nitrous oxide N₂O. Argon (Ar) gas may, for example, also be used during deposition of the cladding or passivation layer 15. The plasma is an inductively coupled plasma ICP.

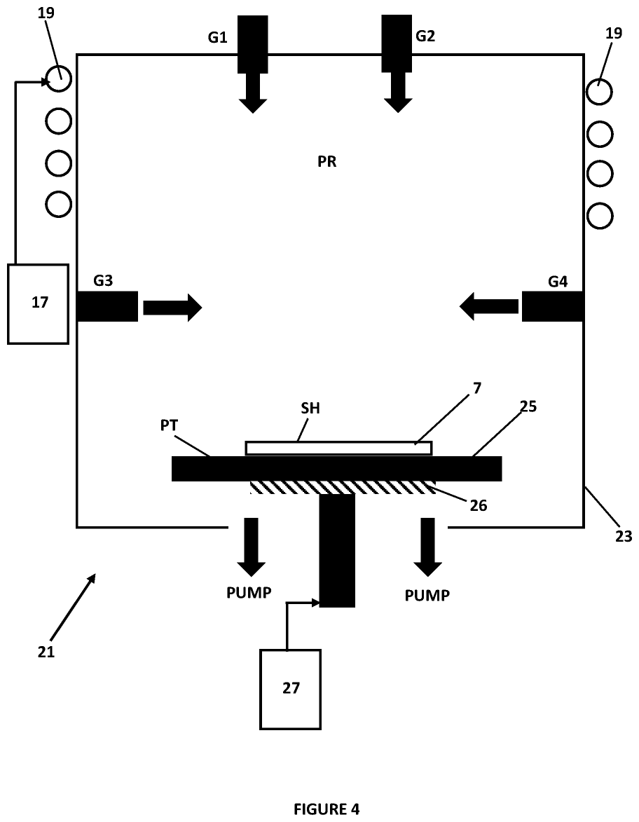

An ICP power source 17 generates (see, for example, FIG. 4) a plasma or high-density plasma through inductive coupling between a radio frequency (RF) antenna and the plasma. An induction coil 19 is excited or powered by an RF power source or voltage generator 17, and the plasma is generated by coupling energy to the plasma through the generation of a magnetic field by the RF power source 17 passing a high frequency current through the induction coil 19. The inductively coupled plasma ICP is generated remotely.

The silicon dioxide (SiO₂) layer or material 15 is deposited by inductively coupled plasma plasma-enhanced chemical vapor deposition ICP-PECVD using a plasma-enhanced chemical vapor deposition ICP-PECVD tool or reactor 21. The silicon dioxide (SiO₂) layer or material 15 may, for example, have a thickness between 1 μm and 4 μm.

The ICP-PECVD tool or reactor 21 includes a reactor chamber 23 inside which the substrate 7 or the plurality of optical waveguides 3 or optical waveguide cores 3 is placed (for example, supported on the substrate 7), for example, on electrode 25. A heater 26 is configured to heat the substrate 7 and/or the plurality of optical waveguides 3 or optical waveguide cores 3 to a predetermined temperature during deposition of the silicon dioxide (SiO₂) layer or material 15. The heater 26 is, for example, a resistive electric heater. The plurality of optical waveguides 3 or optical waveguide cores 3 are, for example, provided on the substrate 7, as for example shown in FIG. 1D and the at least one silicon dioxide (SiO₂) layer or material 15 is deposited onto or directly onto the optical waveguides 3 or optical waveguide cores 3 (the outer surfaces S1 thereof) to form the cladding or passivation layer 15 of the optical waveguide device 1.

The Inductively coupled plasma ICP Is generated at a distance from the provided substrate 7 or the plurality of optical waveguides 3 or optical waveguide cores 3, and the electrode 25.

The ICP-PECVD tool or reactor 21 also includes a pump, such as a vacuum pump, for removing gases or gas particles from chamber 23 and creating a partial vacuum. A pressure in the reaction chamber 23 is typically between, for example, 1×10⁻³ Torr and 50×10⁻³ Torr. A plurality of gas inlets G1, G2, G3, G4 provide the required precursors to the ICP-PECVD tool or reactor 21 to permit material deposition onto the substrate 7 and/or the plurality of optical waveguides 3 or optical waveguide cores 3. For the deposition of the silicon dioxide (SiO₂) layer or material 15, SiCl₄ gas/vapor, O₂ gas and argon (Ar) gas are flowed in or into the chamber 23 using gas inlets.

For example, the O₂ gas is flowed into the chamber 23, for example, via one or both inlets G1, G2 (for example, shower head type inlets) and undergoes induction excitation and the inductively coupled plasma is generated in the plasma region PR. The O₂ gas is flowed to the inlet(s) G1, G2 from an O₂ gas source or supply (not shown). The SiCl₄ gas/vapor is flowed into the chamber, for example, from a liquid source (not shown) via a lower inlet G3, G4 located closer to the substrate 7. The argon (Ar) gas is also flowed in via these or at least one of these lower inlets G3, G4.

For the deposition of the silicon dioxide (SiO₂) layer or material 15A, the SiCl₄ gas flow is, for example, between 25 and 35 standard cubic centimeters per minute (sccm), an O₂ gas flow is, for example, between 60 and 120 sccm, and an Ar gas flow is, for example, between 10 and 30 sccm.

The RF power source or voltage generator 17, is for example, a 2 MHz RF or MF generator for providing power to the coil 19. A RF bias source or voltage generator 27 is also present to provide a RF bias to the substrate electrode 25 and permits to control ion acceleration in the direction of the substrate 7. The RF bias source or voltage generator 27 is, for example, a 13.56 MHz RF generator.

The silicon dioxide layer or material 15 is deposited on the optical waveguide or optical waveguide core 3 at temperature less than or equal to 500° C., or preferably less than or equal to 400° C., or most preferably less than or equal to 300° C. The silicon dioxide layer or material 15 is deposited on the optical waveguide or optical waveguide core 3 at a temperature between 250° C. and 425° C. (extremities included), or 250° C. and 375° C. (extremities included) or 250° C. and 350° C. (extremities included), or 250° C. and 325° C. (extremities included) or 250° C. and 300° C. (extremities included), or 275° C. and 425° C. (extremities included), or 275° C. and 375° C. (extremities included) or 275° C. and 350° C. (extremities included), or 275° C. and 325° C. (extremities included) or 275° C. and 300° C. (extremities included), or between 200° C. and 300° C. (extremities included).

The temperature is set, for example, by the heater 26. The temperature is measured, for example, at the electrode 25 (for example at or from a plate PT of the electrode) upon which the supporting substrate 7 is located and in contact. For example, it is measured using a temperature sensor such as a thermocouple.

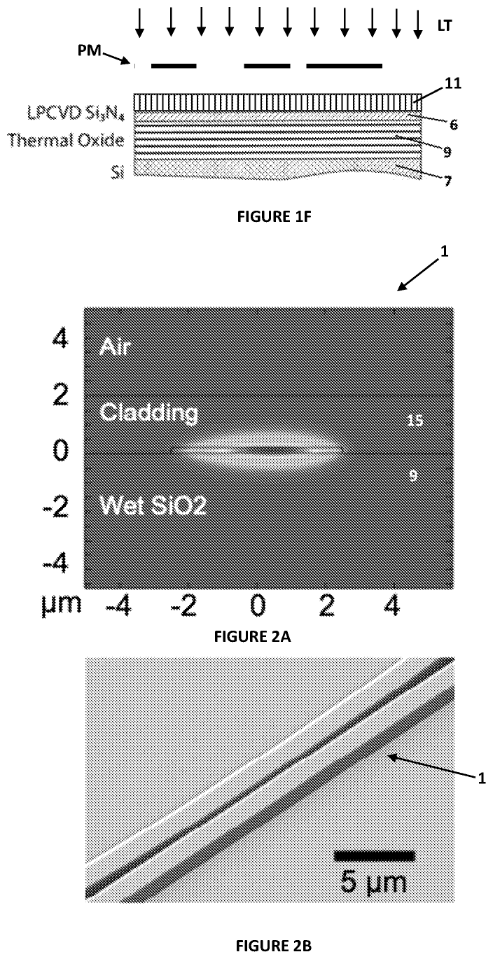

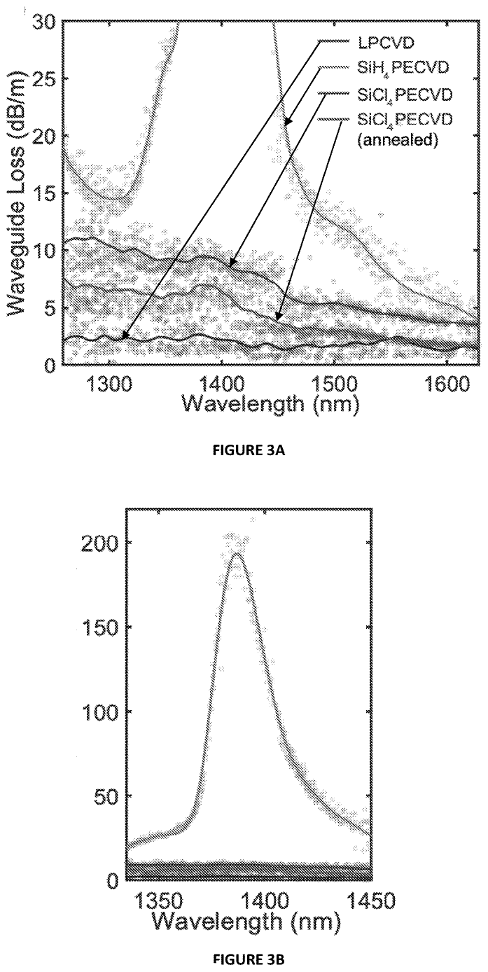

The exemplary plasma-enhanced chemical vapor deposition ICP-PECVD tool or reactor 21 used to deposit the silicon dioxide layer or material 15 deposited in and/or on the waveguides shown in FIG. 2B and for which the measurements are presented in FIGS. 2A and 3A to 3B is an Oxford Instruments PlasmaPro 100 ICPCVD tool.

The silicon dioxide layer or material 15 can, for example, be deposited in an exemplary one-step process, or in an exemplary two-step process, where the following exemplary deposition values were used during a first step of the process: a SiCl₄ gas flow of 32 (standard cubic centimeters per minute) sccm, an O₂ gas flow of 80 sccm, and an Ar gas flow of 15 sccm. The process pressure in the reaction chamber was 4×10⁻³ Torr, the ICP power was 2300 W, the RF bias power was 390 W and the substrate or table temperature was 300° C. The deposition was carried out for a duration of (about) 1500 seconds.

The following exemplary deposition values were used during a second step of the process: a SiCl₄ gas flow of 30 sccm, an O₂ gas flow of 100 sccm, and an Ar gas flow of 15 sccm. The process pressure in the reaction chamber was 8×10⁻³ Torr, the ICP power was 2500 W, the RF bias power was 300 W and the substrate or table temperature was 300° C. The deposition was carried out for a duration of (about) 720 seconds.

An exemplary thickness of about 1.8 μm of the silicon dioxide layer or material 15 was deposited. Such value parameters are optimized for the Oxford Instruments PlasmaPro 100 tool. With a different chamber configuration, these values may require adaptations.

The second step may have a reduced SiCl₄ gas flow relative to the first step. The second step may also have an increased O₂ gas flow and/or RF bias power relative to the first step.

The second step permits to reduce the chlorine content in the deposited film 15.

However, the silicon dioxide layer or material 15 may be deposited using only the first step of the process, the deposition is, for example, extended to deposit the targeted film thickness, which was 1.8 μm in this exemplary case.

The above indicated time duration ratio of the first and second steps of the process is exemplary, this ratio can vary in a wide range (for example, 0 to 80%). For example, 0% in the case where only the first step is carried out, and, for example, between 1% and 80% when both the first and second steps are carried out.

Optionally, prior to deposition, a chamber conditioning process may be performed, which involves carrying out the same deposition but on a dummy wafer or substrate, prior to the production deposition. This permits to reduce or eliminate any impact of residual hydrogen in the process chamber may have during production deposition.

The optical loss of the film 15 deposited according to the present disclosure was evaluated by depositing a layer of SiO₂, of about 1.8 μm thickness by ICP-PECVD at 300° C. using SiCl₄, according to the present disclosure, on top of a 200 nm (thickness (y-direction))×5 μm (width (x-direction)) silicon nitride ring resonator as the top cladding layer; and then a separate deposition using SiH₄ was carried out at 300° C. on top of a separate 200 nm×5 μm silicon nitride ring resonator as the top cladding layer, and furthermore a deposition of a 3 μm thick SiO₂ layer by LPCVD at >400° C. (first 1 μm with TEOS process, and second 2 μm with SiH4 based LTO process) on top of a 200 nm×5 μm silicon nitride ring resonator as the top cladding. The LPCVD sample is annealed at 1200° C. for 11 hours. The optical loss was evaluated by comparing the resonance linewidths (FIGS. 3A and 3B). While the reference PECVD film deposited using SiH₄ and O₂ shows a very strong absorption peak at 1380 nm (see FIGS. 3A and 3B), this absorption peak is barely if at all discernible for the SiCl₄ based films (see flat bottom lines under the absorption peak of FIG. 3B). The waveguide loss is significantly lower in the waveguide devices produced by the SiCl₄ based ICP PECVD method of the present disclosure, across a wide wavelength range, between 1300 nm and 1500 nm, and in particular between 1350 nm and 1450 nm.

Conservatively including the higher scattering loss of the thinner PECVD film, the estimated material loss of the SiO₂ film from SiCl₄ is only slightly higher than the baseline annealed higher temperature 1200° C. LPCVD process fabricated upper waveguide cladding by less than 12 dBm⁻¹ at 1550 nm. Advantageously, a low waveguide loss is maintained across the entire characterization range of 1260 nm to 1625 nm for the ICP PECVD deposited cladding at 300° C. using SiCl₄, according to the present disclosure.

The deposited silicon dioxide SiO₂ layer or material 15 is (substantially) OH absorption-free or (substantially) OH absorption peak-free, or SiO—H absorption peak-free.

To even further reduce optical loss, thermal annealing of the cladded waveguides can, for example, be carried out (only) after deposition of the silicon dioxide (SiO₂) layer or material 15. The thermal annealing may be carried out at moderate temperatures, for example, at a temperature of 500° C. or between 400° C. and 500° C. (extremity values included), and for a time duration of, for example, between 30 and 700 minutes, or between 30 and 90 minutes. This optional annealing is, for example, done in a separate furnace, for example, in an oxygen or nitrogen atmosphere. Loss in the cladded waveguides was further reduced by about 2 dB m⁻¹ with 1 h of annealing at 500° C. (as shown in FIGS. 3A and 3B).

FIG. 2A shows the measured fundamental TE mode of one of the Si₃N₄ ring resonators, and FIG. 2B shows a top view scanning electron microscopy image of the SiO₂ cladding deposited on side-by-side LNOI waveguides, and in between the gap between the LNOI waveguides.

Deposition at such low temperatures are favorable to crystalline materials such as LiNbO₃ used in the waveguide cores and allows to preserve their efficient second-order nonlinearity and key device functionalities like agile electro-optic tuning and highly efficient nonlinear wavelength conversion.

Moreover, this low temperature deposition process is compatible with CMOS devices and integrated photonics platforms including the LiNbO₃ on insulator (LNOI) platform.

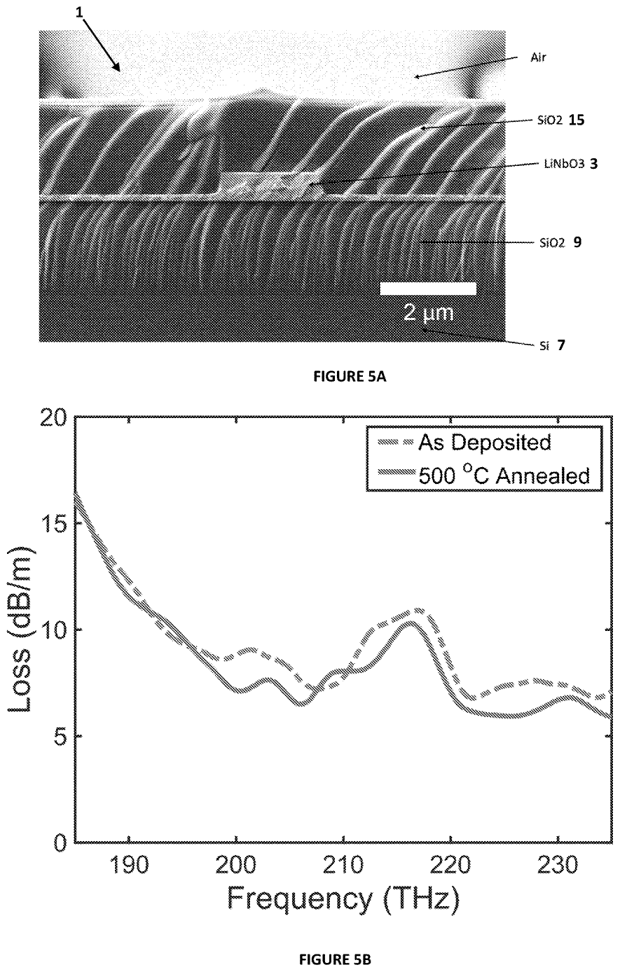

FIG. 5A is a cross-sectional SEM image of a LiNbO₃ on insulator waveguides (LNOI) produced by the optical waveguide device fabrication method of the present disclosure. FIG. 5B shows the measured waveguide optical loss for the LiNbO₃ on insulator waveguides (LNOI) produced by the optical waveguide device fabrication method of the present disclosure. The relatively low loss manifests the compatibility of the method of the present disclosure with the technologically important LNOI photonics platform.

Compared with the commonly used low-pressure chemical vapor deposition (LPCVD) process that require deposition at >400° C. and annealing at >1100° C. to achieve low absorption loss, the process of the present disclosure at a deposition temperature, for example, <300° C.

Moreover, optical absorption and optical loss is significantly reduced by the precursors that are hydrogen-free precursors, or hydrogen isotope-free precursors, or deuterium-free precursors. Silicon tetrachloride and an oxidizer (O₂, optionally combined with N₂O) are instead used as the precursors, instead of hydrogen containing substances, permitting to assure the reduced absorption loss. A hydrogen-free or substantially hydrogen-free low-loss silicon oxide cladding is obtained that can preserve the low-loss waveguides.

As the precursors used are free from hydrogen isotopes, low-OH absorption loss is achieved in the deposited SiO₂ cladding film, or upper SiO₂ cladding film 15 which can reduce the insertion loss and improve performance of integrated photonics devices.

The absorption or optical loss characteristic peak in the near-infrared (that is at 1380 nm or about (±5 nm) 1380 nm, or that includes the wavelength of 1380 nm) due to a vibration overtone of OH bonds formed by hydrogen impurity trapped in the deposited silicon oxide layer or film is eliminated or reduced to an optical waveguide loss value of less than 15 dB/m or 15 dB/m at 1380 nm.

During deposition of the silicon dioxide layer or material 15, the ICP excitation power, provided by the RF power source or voltage generator 17 is, for example, preferably greater than 400 W. The Inventors found that this provided a cladding or passivation layer of relatively lower optical loss compared to lower ICP excitation powers. More preferably, the ICP excitation power is, for example, greater than or equal to 1600 W to provide cladding layers 15 of low optical loss.

A bias radiofrequency power, provided or applied by the RF bias source or voltage generator 27 to the substrate electrode 25 during deposition of the silicon dioxide SiO₂ layer or material 15, is greater than 100 W. The bias RF power allows, for example, to displace radicals or ions present in the plasma towards the substrate 7 and improve the quality of deposited material on substrate 7 by re-sputtering and densification. The Inventors found that the film 15 deposited under such a condition reduced hygroscopicity of the cladding or passivation layer 15 of the optical waveguide device. This avoids deposition of a silicon oxide layer 15 that is strongly hygroscopic and avoids optical losses that appear when the optical device is stored in air over a given time duration of, for example, 1 week. In a preferred embodiment, the bias radiofrequency power is greater than or equal to 180 W, or the bias radiofrequency power is, for example, between 180 W and 400 W.

The Inventors also found that such bias powers have the additional benefit of providing an improving gap-filling by the silicon oxide cladding layer 15 between side-by-side waveguides.

The Inventors further found that using a high SiCl₄ gas flow for example of 30 sccm, or greater than 30 sccm provides a higher layer or material deposition rate of the silicon dioxide SiO₂ layer or material 15 during deposition and permits to provide a cladding or passivation layer of the optical waveguide device of lower optical loss, such loss may be coming from possible residual hydrogen that may be present in the process chamber 23. A moderate bias power, for example, between for example 180 W and 400 W is preferably applied simultaneously to this high precursor gas flow.

A further aspect of the present disclosure concerns an optical waveguide device 1 produced or provided by the above-described deposition method.

A further aspect of the present disclosure concerns a photonic integrated circuit including the optical waveguide device 1 produced or provided by the method of the present disclosure.

While the invention has been disclosed with reference to certain preferred embodiments, numerous modifications, alterations, and changes to the described embodiments, and equivalents thereof, are possible without departing from the sphere and scope of the invention. Accordingly, it is intended that the invention not be limited to the described embodiments and be given the broadest reasonable interpretation in accordance with the language of the appended claims. The features of any one of the above-described embodiments may be included in any other embodiment described herein.

1. Optical waveguide device fabrication method, the method comprising:
providing at least one of an optical waveguide and an optical waveguide core;
depositing at least one layer and/or material comprising silicon dioxide onto the at least one of the optical waveguide and the optical waveguide core to form a cladding and/or passivation layer of the optical waveguide device,
wherein the at least one of the optical waveguide and the optical waveguide core comprises at least one of silicon nitride, lithium niobate, lithium tantalate, barium titanate, gallium phosphide, aluminum oxide, and aluminum gallium arsenide;
wherein the at least one layer and/or material comprising silicon dioxide is deposited by plasma-enhanced chemical vapor deposition using precursors comprising or consisting of silicon tetrachloride and at least one oxidizer, the plasma being an inductively coupled plasma.

2. Method according to claim 1, wherein the method is comprises an optical waveguide device fabrication method for removing, from the fabricated optical waveguide device, an optical absorption near-infrared characteristic peak due to a vibration overtone of OH bonds.

3. Method according to claim 2, wherein a bias radiofrequency power, provided by at least one of a radio frequency bias source and a voltage generator during deposition of the at least one layer and/or material comprising silicon dioxide, is between 180 W and 400 W, and an inductively coupled plasma excitation power is greater than or equal to 1600 W.

4. Method according to claim 1, wherein the at least one oxidizer includes oxygen and/or nitrous oxide.

5. Method according to claim 1, wherein the at least one layer and/or material comprising silicon dioxide is deposited by inductively coupled plasma plasma-enhanced chemical vapor deposition.

6. Method according to claim 1, wherein an inductively coupled plasma excitation power, provided by at least one of a radio frequency power source and a voltage generator during deposition of the at least one layer and/or material comprising silicon dioxide, is greater than 400 W to provide the cladding and/or passivation layer of the optical waveguide device of lower optical loss.

7. Method according to claim 6, wherein an inductively coupled plasma (ICP) excitation power is greater than or equal to 1600 W.

8. Method according to claim 6, wherein a bias radiofrequency power, provided by at least one of a radio frequency bias source and a voltage generator during deposition of the at least one layer and/or material comprising silicon dioxide, is greater than 100 W to reduce hygroscopicity of the cladding and/or passivation layer of the optical waveguide device.

9. Method according to claim 8, wherein the bias radiofrequency power is greater than or equal to 180 W.

10. Method according to claim 9, wherein the bias radiofrequency power is between 180 W and 400 W.

11. Method according to claim 1, wherein the at least one layer and/or material comprising silicon dioxide is deposited on at least one of the optical waveguide and the optical waveguide core, at temperature less than or equal to 300° C.

12. Method according to claim 1, wherein the at least one layer and/or material comprising silicon dioxide is deposited on the at least one of the optical waveguide and the optical waveguide core at temperature and/or substrate temperature between 250° C. and 425° C., the extremity values included.

13. Method according to claim 1, wherein the at least one layer and/or material comprising silicon dioxide is deposited on the at least one of the optical waveguide and the optical waveguide core at temperature and/or substrate temperature between 200° C. and 300° C., the extremity values included.

14. Method according to claim 1, wherein the precursors are at least one of hydrogen-free precursors, hydrogen isotope-free precursors, and deuterium-free precursors.

15. Method according to claim 1, wherein the at least one of the optical waveguide and the optical waveguide core is included on at least one of a photonic integrated circuit, at least one substrate, and at least one CMOS substrate.

16. Method according to claim 1, wherein the at least one of the optical waveguide and the optical waveguide core comprises at least one of silicon nitride, erbium-doped silicon nitride, or lithium niobate.

17. Method according to claim 1, further including carrying out thermal annealing only after deposition of the at least one layer and/or material comprising silicon dioxide, wherein thermal annealing is carrying out at a temperature between 400° C. and 500° C., and for a time duration of between 30 and 700 minutes.

18. Method according to claim 1, further including carrying out thermal annealing only after deposition of the at least one layer and/or material comprising silicon dioxide, wherein thermal annealing is carrying out at a temperature of about 500° C.

19. Method according to claim 1, wherein the deposited at least one layer and/or material comprising silicon dioxide is at least one of OH absorption-free and OH absorption peak-free.

20-22. (canceled)
